(19) United States
(12) Patent Application Publication
(10) Pub. No.: US 2009/0239364 A1
(43) Pub. Date: Sep. 24, 2009

(54) METHOD FOR FORMING INSULATING FILM AND METHOD FOR MANUFACTURING SEMICONDUCTOR DEVICE

(75) Inventors: Tatsuo Nishita, Hyogo (JP); Toshio Nakanishi, Hyogo (JP); Shuuichi Ishizuka, Yamanashi (JP); Tomoe Nakayama, Osaka (JP); Yutaka Fujino, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/910,332

(22) PCT Filed: Mar. 28, 2006
(86) PCT No.: PCT/JP2006/306288

§ 371 Date: May 22, 2008

(30) Foreign Application Priority Data
Mar. 30, 2005 (JP) 2005-099408
Oct. 5, 2005 (JP) 2005-292346

(51) Int. Cl. H01L 21/31; H01L 21/28; C23C 16/511

(52) U.S. Cl. 438/585; 438/772; 118/723 AN; 257/E21.24; 257/E21.19

(57) ABSTRACT

Disclosed is a method for forming a gate insulating film comprising an oxidation step wherein a silicon oxide film is formed by having an oxygen-containing plasma act on silicon in the surface of an object to be processed in a processing chamber of a plasma processing apparatus. The processing temperature in the oxidation step is more than 600° C. and not more than 1000° C., and the oxygen-containing plasma is formed by introducing an oxygen-containing processing gas containing at least a rare gas and an oxygen gas into the process chamber while introducing a high frequency wave or microwave into the process chamber through an antenna.

### FIELD OF THE INVENTION

The present invention relates to a method of fabricating an insulating film in which an object to be processed such as a semiconductor substrate is processed and an insulating film is formed by using plasma; and a method of fabricating a semiconductor device such as a transistor using the insulating film.

### BACKGROUND OF THE INVENTION

In fabrication processes for various kinds of semiconductor devices, for example, a silicon oxide film such as SiO₂ is formed as a gate insulating film of a transistor. To suppress an increase in a tunnel current or the punchthrough phenomenon of boron (B) which is p-type impurity, the silicon oxide film is nitrided to a silicon oxynitride (SiON) film to be used as the gate insulating film.

Methods of forming the silicon oxide film are divided into a thermal oxidation process using an oxidation furnace or a rapid thermal process (RTP) apparatus, and a plasma oxidation process using a plasma process apparatus. For example, in a wet oxidation process using the oxidation furnace, which is one of the thermal oxidation process, a silicon substrate is heated at a temperature higher than or equal to 800° C. and is exposed in an oxidation atmosphere by using a water vapor generator (WVG), thereby oxidizing a silicon surface to form an oxide film.

Meanwhile, as a plasma oxidation process, there has been proposed a method of forming the silicon oxide film by performing the plasma oxidation process at a low temperature lower than or equal to 550° C. using the plasma process apparatus for generating plasma by introducing microwave into a processing chamber by a radial line slot antenna (see, for example, Patent Document 1).

(Patent Document 1) Japanese Patent Application Publication No. 2001-160555 (e.g., Paragraph 0015).

Conventionally, it has been thought that the silicon oxide film of good quality can be formed by performing the thermal oxidation process. However, in the thermal oxidation process, when a film thickness is very thin, a leakage current increases due to the tunneling phenomenon that electrons pass through the oxide film (insulating film) by quantum mechanical effects, or a deterioration in the film quality. Thus, there is a problem in that the leakage current adversely affects electrical characteristics of a semiconductor device which uses, as a gate insulating film, a silicon oxide film or a silicon oxynitride film formed by nitriding the silicon oxide film.

Further, recently, as a consequence of the miniaturization of a semiconductor device, a thickness of a gate insulating film is becoming smaller. Specifically, since a node of 65 nm or less needs a thin gate insulating film whose thickness is a few nanometers or smaller, it is difficult to obtain the silicon oxide film of a desired layer quality by the conventional thermal oxidation process or plasma oxidation process.

### SUMMARY OF THE INVENTION

In view of the above, the present invention provides a method of fabricating an insulating film in which a high-quality insulating film is formed to acquire good electrical characteristics of a semiconductor device while decreasing the thickness of the layer.

In accordance with a first aspect of the present invention, there is provided a method of forming an insulating film, including performing an oxidation process to form a silicon oxide film by applying oxygen-containing plasma onto silicon in a surface of an object to be processed in a processing chamber of a plasma processing apparatus, wherein a processing temperature in the oxidation process is higher than 600° C. and lower than or equal to 1000° C., and wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

It is preferable that, in the first aspect of the present invention, a dielectric plate having a plurality of through holes is interposed between a plasma generation region and the object to be processed in the processing chamber in the oxidation process.

Further, it is preferable that each of the though holes has a diameter of 2.5 to 12 mm, and a ratio of a total opening area of the through holes to an area of the object to be processed in an area of the dielectric plate corresponding to the object to be processed is 10 to 50%.

Further, it is preferable that, in the oxidation process, a processing pressure is 1.33 to 1333 Pa.

Further, it is preferable that a thickness of the silicon oxide film is 0.2 to 10 nm.

In accordance with a second aspect of the present invention, there is provided a method of forming an insulating film, including performing an oxidation process to form a silicon oxide film by applying oxygen-containing plasma onto silicon in the surface of an object to be processed in a processing chamber of plasma processing apparatus; and performing a nitriding process to form a silicon oxynitride film by applying nitrogen-containing plasma onto the silicon oxide film formed in the oxidation process, wherein a processing temperature in the oxidation process is higher than 600° C. and lower than or equal to 1000° C., and wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

It is preferable that, in the second aspect of the present invention, the nitrogen-containing plasma is formed by introducing a nitrogen-containing processing gas including at least a rare gas and a nitrogen gas into a processing chamber, and, at the same time, applying a high frequency wave or a microwave into the processing chamber via the antenna.

Further, it is possible that the nitriding process and the oxidation process are performed in the same processing chamber, or the nitriding process and the oxidation process are respectively performed in separate processing chambers connected to each other in a state capable of being vacuum exhausted.

Further, it is preferable that, in the oxidation process, a dielectric plate having a plurality of through holes is interposed between a plasma generation region and the object to be processed in the processing chamber.

Further, it is preferable that each of the though holes has a diameter of 2.5 to 12 mm, and a ratio of a total opening area of the through holes to an area of the object to be processed in an area of the dielectric plate corresponding to the object to be processed is 10 to 50%.

Further, it is preferable that a processing pressure is 1.33 to 1333 Pa in the oxidation process. Further, it is preferable that a thickness of the silicon oxide film is 0.2 to 10 nm.

In accordance with a third aspect of the present invention, there is provided a control program running on a computer that is executed to control a plasma processing apparatus to perform an oxidation process for forming a silicon oxide film by applying oxygen-containing plasma onto silicon of the surface in an object to be processed in a processing chamber of the plasma processing apparatus, wherein a processing temperature in the oxidation process is higher than 600° C. and lower than or equal to 1000° C., and wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

In accordance with a fourth aspect of the present invention, there is provided a computer-readable storage medium that stores a control program running on a computer, wherein the control program is executed to control a plasma processing apparatus to perform an oxidation process for forming a silicon oxide film by applying oxygen-containing plasma onto silicon of the surface in an object to be processed in a processing chamber of the plasma processing apparatus, wherein a processing temperature in the oxidation process is higher than 600° C. and lower than or equal to 1000° C., and wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

In accordance with a fifth aspect of the present invention, there is provided a plasma processing apparatus including a plasma generation unit for generating plasma; a processing chamber capable of being vacuum exhausted, for processing an object to be processed by the plasma; a substrate supporting table on which the object to be processed is mounted in the processing chamber; and a control unit for controlling to perform an oxidation process for oxidizing the object to be processed by oxygen-containing plasma formed by introducing an oxygen-containing processing gas including at least a rare gas and an oxygen gas into the processing chamber, and, at the same time, introducing a high frequency wave or a microwave into the processing chamber via an antenna at a processing temperature of higher than 600° C. and lower than or equal to 1000° C.

In accordance with a sixth aspect of the present invention, there is provided a method of forming a semiconductor device, comprising forming a gate electrode on the insulating film formed by the method of the first aspect.

In accordance with a seventh aspect of the present invention, there is provided a method of forming a semiconductor device, comprising forming a gate electrode on the insulating film formed by the method of the second aspect.

In accordance with the present invention, by performing an oxidation process at a high temperature ranging from 600° C. to 1000° C. using a microwave introduced into a processing chamber by an antenna and an oxygen-containing plasma formed by a processing gas including at least a rare gas and an oxygen gas, a plasma damage can be efficiently prevented, and a silicon oxide film of a high quality can be formed. Further, by using the silicon oxide film or, when necessary, a silicon oxynitride film formed by nitriding the silicon oxide film as an insulating film such as a gate insulating film, the electrical characteristics of a semiconductor device such as a transistor can be enhanced.

That is, a semiconductor device having an excellent current driving characteristic can be produced by using the insulating film fabricated by the method in accordance with the present invention. Especially, even when the gate insulating film is formed as a thin film of 1 nm or less, an ideal oxide film that is dense and has fewer traps can be acquired. Thus, the increase in the tunnel current can be suppressed, and the driving current can be greatly increased compared to a conventional case of using a thermal oxidation layer. As a result, it is possible to improve the performance of the semiconductor device.

### BRIEF DESCRIPTION OF THE DRAWINGS

FIG. 1 is a schematic view of a semiconductor manufacturing apparatus in accordance with the present invention;

FIG. 2 is a schematic sectional view of a plasma processing apparatus usable for a plasma oxidation process;

FIG. 3A is a plan view for describing a plate;

FIG. 3B is a cross sectional view of a main part of the plate;

FIG. 4 is a view for describing a planar antenna member;

FIG. 5A is a schematic view for showing a cross sectional structure of a wafer W for representing a process of forming a gate insulating film, in which the plasma oxidation process is being performed;

FIG. 5B is a schematic view for showing a cross sectional structure of a wafer W for representing a process of forming a gate insulating film, in which the plasma oxidation process has been completed;

FIG. 5C is a schematic view for showing a cross sectional structure of a wafer W for representing a process of forming a gate insulating film, in which a plasma nitriding process is being performed;

FIG. 5D is a schematic view for showing a cross sectional structure of a wafer W for representing a process of forming a gate insulating film, in which the plasma nitriding process has been completed;

FIG. 6 is a schematic cross sectional view of a plasma processing apparatus usable for a plasma nitriding process;

FIG. 7A is a schematic view of a gate electrode structure of a transistor, which illustrates a tungsten polycide structure;

FIG. 7B is a schematic view of the gate electrode structure of the transistor, which illustrates a tungsten polymetal structure;

FIG. 7C is a schematic view of the gate electrode structure of the transistor, which illustrates a tungsten metal gate structure;

FIG. 8 is a graph for showing a Gm curve of the transistor;

FIG. 9 is a graph for showing an Iₒₙ-Jg plot of the transistor;

FIG. 10 is a graph for showing a relationship between an oxidation processing time and a film thickness;

FIG. 11 is a partial enlarged view of FIG. 10;

FIG. 12 is a graph for showing results of running tests;

FIG. 13 is a graph for showing results of etching resistance tests;

FIG. 14 is a graph for showing results of measuring the interface roughness;

FIG. 15 is a graph for showing results of measuring the film density;

FIG. 16 is a graph for showing a relationship between an equivalent oxide thickness (EOT) and Iₒₙ in an NMOS transistor; and

FIG. 17 is a graph for showing a relationship between the EOT and the maximum value of Gm in the NMOS transistor.

### DETAILED DESCRIPTION OF THE EMBODIMENTS

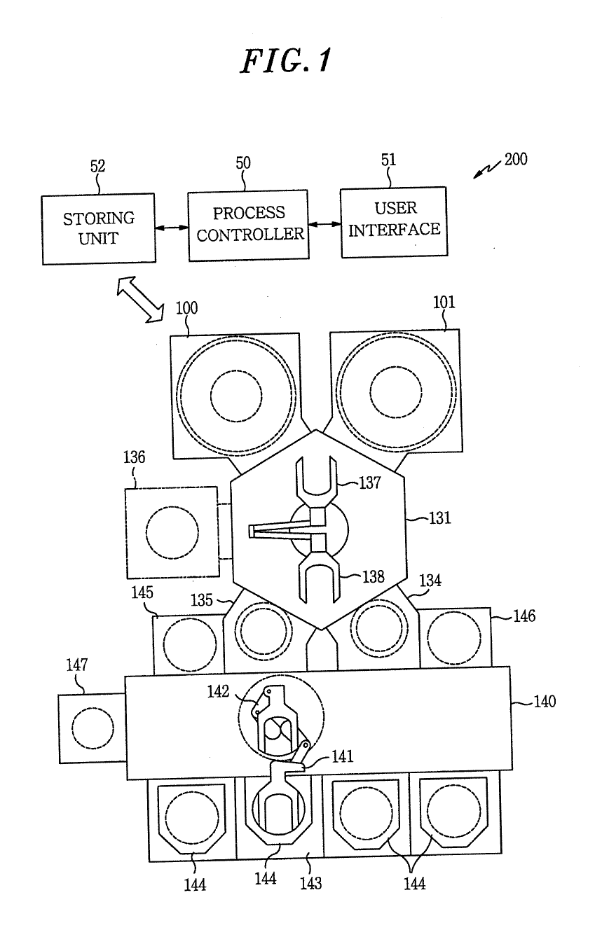

Hereinafter, embodiments of the present invention will be described in detail with reference to the accompanying drawings which form a part hereof. FIG. 1 is a schematic view for showing a configuration of a semiconductor manufacturing apparatus 200 for carrying out a method of fabricating a gate insulating film in accordance with an embodiment of the present invention. A transfer chamber 131 for transferring a semiconductor wafer (hereinafter, simply referred to as “wafer”) W is placed approximately in the middle of the semiconductor manufacturing apparatus 200. Around the transfer chamber 131 are arranged plasma processing apparatuses 100 and 101 as plasma processing units for performing some kinds of processes on the wafer W; a gate valve (not shown) for connecting and disconnecting between the processing chambers; two load-lock units 134 and 135 for transferring the wafer W between the transfer chamber 131 and an atmospheric transfer chamber 140, and a heating unit 136 for heating (annealing) the wafer W.

A preliminary cooling unit 145 and a cooling unit 146 for performing various operations for preliminary cooling and cooling are respectively disposed beside the load-lock units 134 and 135. When the load-lock units 134 and 135 are used as a cooling unit, the preliminary cooling unit 145 and the cooling unit 146 may be omitted.

Inside of the transfer chamber 131 are disposed transfer arms 137 and 138 for transferring the wafer W between the units.

The atmospheric transfer chamber 140 is connected to the load-lock units 134 and 135, and is provided with transfer units 141 and 142. The atmospheric transfer chamber 140 is kept in a clean environment by clean air flowing downwards. In the atmospheric transfer chamber 140, which is connected to a cassette unit 143, the wafer W is transferred into and out of four cassettes 144 set in the cassette unit 143. An alignment chamber 147 is arranged adjacent to the atmospheric transfer chamber 140, in which an alignment of the wafer W is performed. Further, each component of the semiconductor manufacturing apparatus 200 is configured to be controlled by a process controller 50 having a CPU.

Further, in the semiconductor manufacturing apparatus 200 shown in FIG. 1, after, for example, forming an SiO₂ layer by the plasma processing apparatus 100, the wafer W is transferred to the plasma processing apparatus 101 connected thereto in a vacuum state. In the plasma processing apparatus 101, a surface of the SiO₂ layer can be nitrided. Further, the processes from the SiO₂ layer formation to the nitriding treatment thereof may be performed continuously in a single apparatus, i.e., in each of the plasma processing apparatus 100 and the plasma processing apparatus 101.

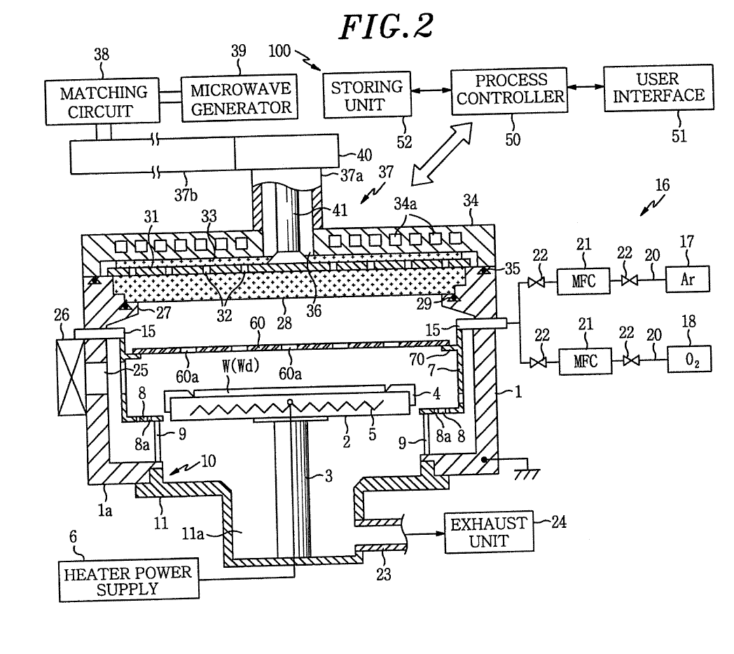

FIG. 2 is a cross sectional view for schematically showing an example of the plasma processing apparatus 100. The plasma processing apparatus 100 is an RLSA microwave plasma processing apparatus that generates a microwave plasma with a high density and a low electron temperature by introducing a microwave into a processing chamber by a planar antenna having a plurality of slots, especially, a radial line slot antenna (RLSA). The plasma processing apparatus may preferably be used for forming a gate insulating film in fabricating various kinds of semiconductor device such as an MOS transistor, a metal-oxide semiconductor field effect transistor (MOSFET) and the like.

The plasma processing apparatus 100 is air-tightly constituted and has a nearly cylindrical chamber 1 that is grounded. An opening 10 of a circular shape is formed approximately in the middle of a bottom wall 1a of the chamber 1. An exhaust chamber 11 provided in the bottom wall 1a is communicated with the opening 10, and protrudes downward.

A susceptor 2, formed of ceramics such as AlN and the like, is installed in the chamber 1 to horizontally support the wafer W serving as an object to be processed. The susceptor 2 is supported by a supporting member 3 that is formed of ceramics such as AlN and the like in a cylindrical shape and extends upwards from the middle of the bottom of the exhaust chamber 11. A guide ring 4 for guiding the wafer W is provided at an outer peripheral edge of the susceptor 2. Further, a heater 5 of a resistance-heating type is embedded in the susceptor 2 to heat the susceptor 2 by an electric power supplied from a heater power supply 6, thereby heating the wafer W to be processed by using that heat. At this time, a temperature is controllable within a range from, e.g., a room temperature to 1000° C. A cylindrical liner 7 formed of quartz is provided at an inner periphery of the chamber 1. Further, a baffle plate 8 of a ring shape is provided at an outer peripheral part of the susceptor 2. The baffle plate 8, which has a number of gas exhaust ports 8a for uniformly exhausting an inside of the chamber 1, is supported by a plurality of supports 9.

In the susceptor 2, wafer supporting pins (not shown) for supporting and moving up and down the wafer W are installed in a manner that they can move outwards and inwards with respect to a surface of the susceptor 2.

Disposed on the susceptor 2 is a plate 60 that has therein a plurality of through holes for attenuating and then transmitting the energy of active species (ions, radicals and the like) in the plasma. The plate 60 may be formed of, e.g., quartz, dielectric ceramic material such as sapphire, SiN, SiC, Al₂O₃, AlN or the like, or single crystalline silicon, polysilicon, amorphous silicon or the like. In the present embodiment, quartz is used for the plate 60. The plate 60 is supported by engaging an outer peripheral part thereof with a supporting part 70 that protrudes inwardly from the liner 7 in the chamber 1 throughout an entire circumference thereof. Further, while the plate 60 serves to decrease the energy of the active species in the plasma, it can be omitted in case a film thickness of the oxide film to be formed is 5 nm or greater.

It is preferable that the plate 60 is attached at a position near the wafer W. A distance between a lower end of the plate 60 and the wafer W is preferably about 3 to 20 mm, and more preferably about 10 mm. In this case, it is preferable that a distance between an upper end of the plate 60 and a lower end of a transmission plate 28 (to be described later) is about 20 to 50 mm.

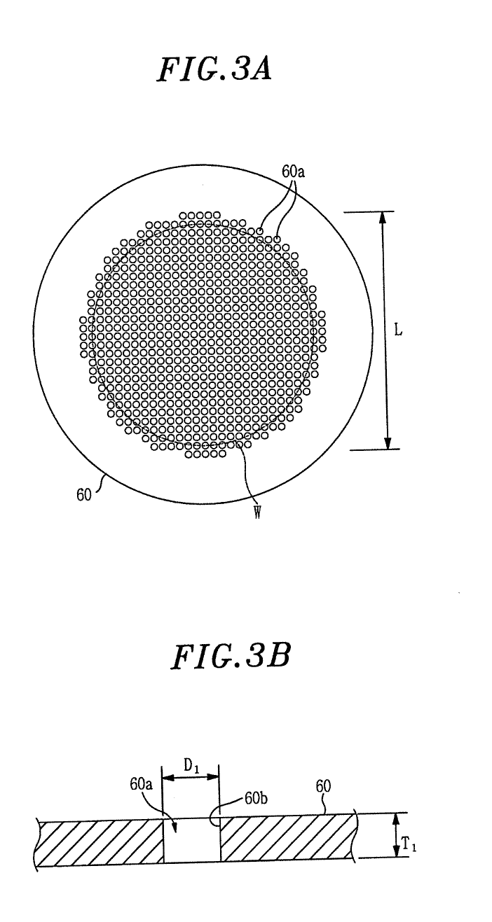

A plurality of through holes 60a is formed in the plate 60. FIGS. 3A and 3B illustrate details of the plate 60, wherein FIG. 3A is a top view thereof, and FIG. 3B is a cross sectional view of a main part thereof.

The through holes 60a of the plate 60 are arranged in an approximately uniform distribution such that an area within which the through holes 60a are distributed is slightly greater than an area that the wafer W occupies indicated by a dashed line in FIG. 3A. More particularly, in FIG. 3A for example, in case of a diameter of the wafer W being 300 mm, the through holes 60a are distributed such that a length L, which is equal to a diameter of a circle connecting an outer periphery of the area within which the through holes 60a are distributed, is elongated outwards beyond a circumference of the wafer W by about 5 to 30 mm. Alternatively, the through holes 60a may be distributed on an entire area of the plate 60.

A diameter D₁ of the through hole 60a may be set as desired. It may be set to be, for example, about 2.5, 5 or 10 mm. The size of the hole may be changed depending on the positions of the through holes 60a. Further, the through holes 60a may be arranged in, for example, a concentric circle shape, a radial shape, a spiral shape or else as desired. Further, a thickness T₁ of the plate 60 is preferably about 2 to 20 mm, and more preferably about 3 to 8 mm.

The plate 60 functions as energy attenuation means for attenuating the energy of the active species in the plasma, such as ions and the like.

That is, by the presence of the plate 60 formed of dielectric material, it is possible to allow radicals in the plasma to be transmitted therethrough while attenuating the energy of high-energy ions such as Ar and N ions and the like. For this purpose, as will be described later, it is preferable to take the following factors into consideration as a whole: an opening area of the through holes 60a of the plate 60; the diameter D₁ of the through hole 60a; shapes or positions of the through holes 60a; the thickness T₁ of the plate 60 (i.e., a height of the wall 60b); an installation position of the plate 60 (e.g., a distance from the wafer W); and the like. As an example, when the diameter of the through hole 60a is set to be 2.5 to 12 mm, it is preferable that a ratio of a total opening area of the through holes 60a to the area of the wafer W is 10 to 50% within the area that the wafer W occupies on the plate 60.

A gas introducing member 15 of a ring shape is provided at a side wall of the chamber 1, and is connected to a gas supply system 16. Further, the gas introducing member may be arranged in a shower shape. The gas supply system 16 includes, for example, an Ar gas supply source 17 and an O₂ gas supply source 18. These gases reach the gas introducing member 15 respectively via gas lines 20, and are introduced from the gas introducing member 15 into the chamber 1. Each of the gas lines 20 is provided with a mass flow controller 21 and a couple of opening/closing valves 22 before and after the mass flow controller 21. Further, other rare gases such as Kr, Xe and He may be used instead of the Ar gas.

A gas exhaust line 23 is connected to a side of the exhaust chamber 11, and a gas exhaust unit 24 including a high speed vacuum pump is connected to the gas exhaust line 23. By operating the gas exhaust unit 24, a gas in the chamber 1 is uniformly discharged into a space 11a of the exhaust chamber 11, and is exhausted via the gas exhaust line 23. Thus, an inside of the chamber 1 can be rapidly depressurized to a specific vacuum level, for example, 0.133 Pa.

On a sidewall of the chamber 1 are provided a transfer port 25 for transferring the wafer between the chamber 1 and a transfer chamber (not shown) adjacent to the plasma processing apparatus 100 and a gate valve 26 for opening and closing the transfer port 25.

An upper part of the chamber 1 includes an opened part, and a supporting part 27 of a ring shape is provided along a circumference of the opened part. The supporting part 27 is provided with a transmission plate 28 formed of dielectric material, for example, quartz or ceramic material such as Al₂O₃, AlN and the like. The transmission plate 28 is for transmitting a microwave, and is airtightly connected to the supporting part 27 via a sealing member 29. Thus, the inside of the chamber 1 is kept airtightly.

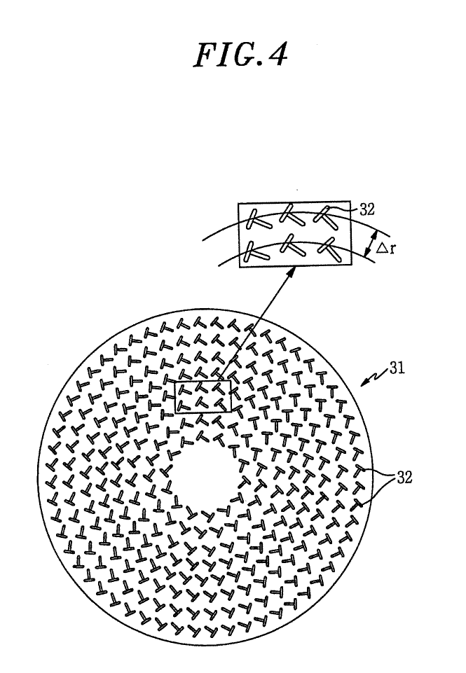

A planar antenna member 31 of a disk shape is installed on the transmission plate 28 to face the susceptor 2. The planar antenna member 31 is fixed by being engaged with an upper end of the sidewall of the chamber 1, and is made of conductive material, for example, an aluminum plate or a copper plate whose surface is gold or silver plated. A number of slots 32 for radiating microwaves are formed to penetrate the planar antenna member 31 in specified patterns. The slot 32 has, for example, a elongated shape as illustrated in FIG. 4. Typically, an adjacent pair of slots 32 is arranged in a “T” shape, whereas the entire slots 32 are arranged in concentric circles. A length of the slot 32 and distances between the slots 32 are determined according to a wavelength λg of the microwave. For example, the slots 32 are arranged to be distanced from each other by λg/4, λg/2 or λg. Further, in FIG. 4, a distance between two adjacent pairs of slots 32 in the concentric circles is indicated as Δr. Further, the slot 32 may be of other shapes such as a round shape or a circular arc shape. Further, the overall distribution of the slots 32 is not limited to be of the concentric circle shape, but the slots 32 may be arranged, for example, in a spiral or radial shape.

A retardation member 33 having a dielectric constant greater than that of a vacuum is provided on an upper side of the planar antenna member 31, and is formed of, for example, quartz or ceramic material such as Al₂O₃, AlN or the like, fluorine-based resin such as polytetrafluoroethylene, or polyimide-based resin. Since a wave length of the microwave is greater in a vacuum, the retardation member 33 has a function of controlling plasma by reducing a wavelength of the microwave. Further, the planar antenna member 31 may be arranged to be in contact with or apart from the transmission plate 28, and the retardation member 33 may be arranged to be in contact with or apart from the planar antenna member 31.

A shield lid 34, made of metal such as aluminum, stainless steel or the like, is provided over an upper side of the chamber 1 to cover the planar antenna member 31 and the retardation member 33. Further, the shield lid 34 functions as a part of a waveguide to allow a microwave transmitted therethrough uniformly. The upper side of the chamber 1 and the shield lid 34 are sealed by a sealing member 35. A cooling water path 34a is formed in the shield lid 34, such that, by flowing cooling water therethrough, the shield lid 34, the retardation member 33, the planar antenna member 31 and the transmission plate 28 can be cooled down. Further, the shield lid 34 is grounded.

An opening 36 is formed in the middle of an upper wall of the shield lid 34, and a waveguide 37 is connected to the opening 36. A microwave generator 39 is connected to an end portion of the waveguide 37 via a matching circuit 38. The microwave having a frequency of, for example, 2.45 GHz, which is generated in the microwave generator 39, is transmitted to the planar antenna member 31 via the waveguide 37. The frequency of the microwave may be 8.35 GHz, 1.98 GHz and the like.

The waveguide 37 includes a coaxial waveguide 37a whose cross section extending upwards from the opening 36 of the shield lid 34 is of a circular shape; and a rectangular waveguide 37b that extends in a horizontal direction, and is connected to an upper end portion of the coaxial waveguide 37a via a mode transducer 40. The mode transducer 40, disposed between the rectangular waveguide 37b and the coaxial waveguide 37a, converts a transmission mode of a microwave transmitted via the rectangular waveguide 37b in a TE mode into a TEM mode. An inner conductor 41 is extended to a center of the coaxial waveguide 37a, and a lower end portion thereof is connected and fixed to a center of the planar antenna member 31. Thus, the microwave is transmitted efficiently and uniformly in a radial direction to the planar antenna member 31 via the inner conductor 41 of the coaxial waveguide 37a.

Each component of the plasma processing apparatus 100 is connected to and controlled by a process controller 50 including a CPU. The process controller 50 is connected to a user interface 51 including a keyboard with which a process operator inputs commands for controlling the plasma processing apparatus 100; a display for showing and indicating an operation state of the plasma processing apparatus 100; and the like.

Furthermore, the process controller 50 is connected to a storage unit 52 for storing a recipe which records a control program (software) and processing condition data to execute various processes by the plasma processing apparatus 100 pursuant to the control of the process controller 50.

Further, by, if necessary, retrieving a desired recipe from the storage unit 52 to have the process controller 50 execute the recipe by, e.g., a command from the user interface 51, a desired process is performed in the plasma processing apparatus 100 under the control of the process controller 50. Besides, the recipe including the control program or processing condition data can be stored in computer readable memory media, for example, CD-ROM, hard disk, flexible disk, flash memory and the like, or can be provided from other devices to be used online by being received via, for example, a dedicated line at any time.

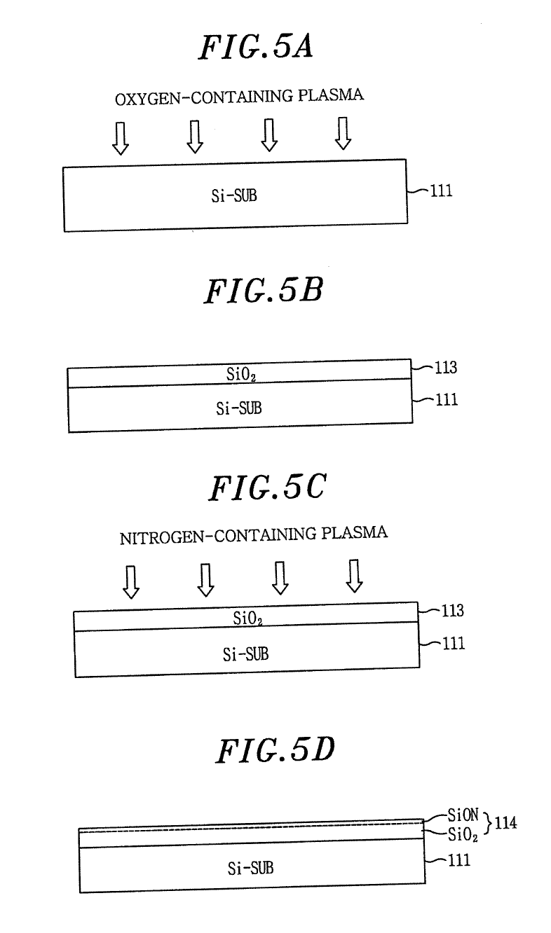

In the plasma processing apparatus 100 of the aforementioned RLSA type as configured above, the process of forming a silicon oxide film 113 by oxidizing a silicon layer 111 on the wafer W may be performed in a sequence of, for example, that shown in FIGS. 5A and 5B. Further, as illustrated in FIGS. 5C and 5D, a surface of thus formed silicon oxide film 113 may be nitrided to form a gate insulating film 114 including a silicon oxynitride film.

In forming the silicon oxide film, the gate valve 26 is opened to carry the wafer W having the silicon layer into the chamber 1 via the transfer port 25. The wafer W is then placed on the susceptor 2. Thereafter, the Ar gas and the O₂ gas are introduced, in a specific amount, from the Ar gas supply source 17 and the O₂ gas supply source 18 of the gas supply system 16 into the chamber 1 via the gas introducing member 15.

Specifically, for example, a flow rate of the rare gases of such as Ar and the like is set to be 200 to 3000 mL/min(sccm), and a flow rate of the O₂ gas is set to be 1 to 600 mL/min(sccm). A pressure in the chamber is adjusted to be a processing pressure of 1.33 to 1333 Pa (10 mTorr to 10 Torr); and preferably, 26.6 to 400 Pa (200 mTorr to 3 Torr). Further, the wafer W is heated to a temperature higher than 600° C. and lower than or equal to 1000° C.; preferably, higher than 700° C. and lower than or equal to 1000° C.; and more preferably, higher than 700° C. and lower than or equal to 900° C. It is preferable that a flow rate ratio of Ar to O₂ is about 2000:1 to 5:1.

Subsequently, the microwave generated from the microwave generator 39 is transmitted to the waveguide 37 via the matching circuit 38. Then, the microwave is transmitted sequentially to the rectangular waveguide 37b, the mode transducer 40 and the coaxial waveguide 37a, and is supplied to the planar antenna member 31. Thereafter, the microwave is radiated into the chamber 1 via the transmission plate 28 from the slots of the planar antenna member 31. The microwave is transmitted in the TE mode in the rectangular waveguide 37b, and this TE mode microwave is converted to a TEM mode microwave by the mode transducer 40 to be transmitted via the coaxial waveguide 37a to the planar antenna member 31. The microwave, radiated into the chamber 1 via the transmission plate 28 from the planar antenna member 31, forms an electric field in the chamber 1, and renders the Ar gas and O₂ gas into a plasma state. As illustrated in FIG. 5A, the silicon layer 111 of the wafer W is processed by the plasma containing oxygen. At this time, it is preferable that the power of the microwave generator 39 is set to be 0.5 to 5 kW; and more preferably, 1 to 3 kW.

Due to the radiation of the microwave from a plurality of slots 32 of the planar antenna member 31, the microwave plasma has a high density of about 1×10¹⁰ to 5×10¹²/cm³, and, in the vicinity of the wafer W, becomes a low electron temperature plasma of about 1.5 eV. Thus formed microwave plasma causes a less plasma damage by ions and the like. Moreover, by the presence of the plate 60, when the plasma formed above the plate 60 is transmitted to the wafer W, the energy of active species (ions and the like) in the plasma is attenuated. Thus, the plasma is generated in a state of low temperature electron in which the temperature of electrons is 1 eV or less under the plate 60, and is 0.7 eV or less in the vicinity of the wafer W. As a result, the plasma damage can be further reduced. Further, oxygen is introduced into silicon by the action of the active species in the plasma, mainly by the action of oxygen radicals (O*) and the like, thereby forming Si—O bonds. As illustrated in FIG. 5B, thus formed silicon oxide film 113 is of a high quality, being dense and having fewer traps. In this manner, by using the plasma processing apparatus 100 and performing the plasma process at a temperature above 600° C., a dense and high-quality silicon oxide film (gate insulating film) can be formed with a thin film thickness of 0.2 to 10 nm; preferably 0.5 to 2.0 nm; and more preferably, 0.8 to 1.2 nm.

Hereinafter, more specific sequence of the plasma oxidation process performed in the plasma processing apparatus 100 will be described. After the wafer W is carried into the chamber 1, the wafer supporting pins (not shown) are, at a first step, moved up to protrude from the susceptor 2. Then, the wafer W is preheated while supported by the wafer supporting pins. The preheat is performed for about 20 seconds while the Ar gas is introduced at the flow rate of 2000 mL/min(sccm) from the Ar gas supply source 17 in a state where the pressure in the chamber 1 is, for example, 266.6 Pa (2 Torr).

Subsequently, at a second step, the wafer supporting pins (not shown) are moved down to mount the wafer W on the susceptor 2. Then, the preheat is continued for about 70 seconds while the Ar gas is introduced at the flow rate of 2000 mL/min(sccm) in a state where the inside of chamber 1 is exhausted. By performing the preheat at the first and second steps, the wafer W is prevented from being deformed due to a sudden rise of a temperature when the wafer W is processed at a high temperature of, for example, 800° C. It is Preferable that the preheat process may be performed until the temperature reaches as high as the processing temperature.

At a third step, the O₂ gas is introduced at the flow rate of 10 mL/min(sccm) from the O₂ gas supply source 18 while the flow rate of the Ar gas is kept unchanged, and the pressure of the chamber 1 is adjusted to 67.7 Pa (500 mTorr). By maintaining this state for about 20 seconds, the flow rates of the gases are stabilized.

Thereafter, at a fourth step, the microwave is generated with a power of, for example, 2 kW, by the microwave generator 39 while the pressure and the flow rates of the gases are kept unchanged. The microwave is then introduced into the chamber 1 via the matching circuit 38, the waveguide 37, the planar antenna member 31 and the like, thereby exciting a plasma. Then, a plasma oxidation process is performed on the wafer W, for example, for about 10 to 15 seconds.

At a fifth step, a plasma ending process is carried out while the microwave is cut off and the pressure and the flow rates of the gases are maintained for about 3 seconds. By performing the first to fifth steps, the plasma oxidation process is completed for a single wafer W in the plasma processing apparatus 100.

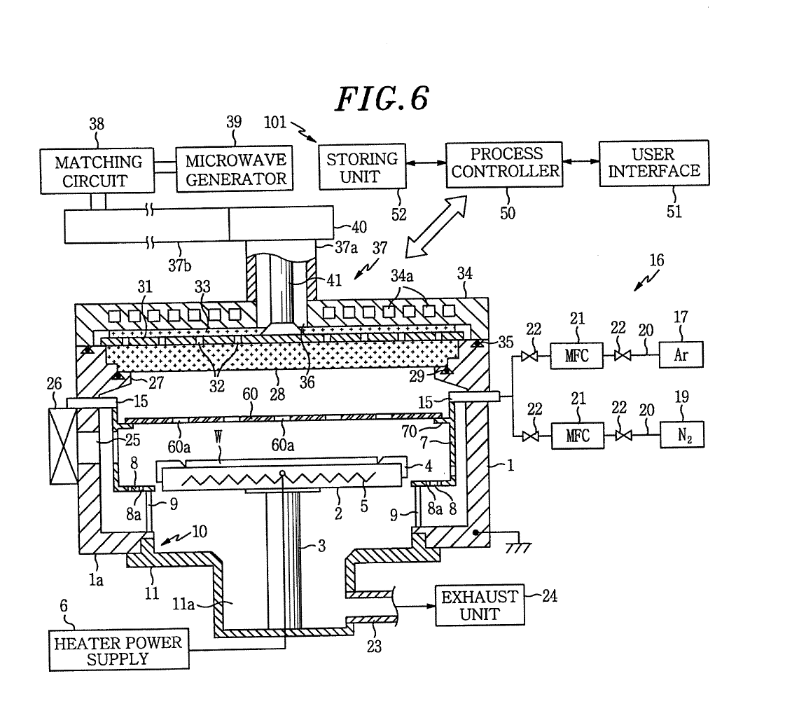

In the present invention, the high-quality silicon oxide film 113 formed by the aforementioned process is usable as a gate insulating film of a semiconductor device. Further, if the silicon oxide film 113 is to be used as the gate insulating film 114, the silicon oxide film 113 may be nitrided to form a silicon nitride film on the surface of the silicon oxide film 113. This nitriding process can be performed by introducing a nitrogen-containing gas into one and a single chamber, i.e., into the plasma processing apparatus 100 of FIG. 2 without changing chambers. However, when the inside of the chamber 1 is in an oxidation atmosphere, it may affect the nitriding process. Therefore, it is preferable that the nitriding process is performed by transferring the wafer W into another chamber. For performing the nitriding process in another chamber, e.g., the plasma processing apparatus 101 illustrated in FIG. 6 may be used. The plasma processing apparatus 101 is of the RLSA type, and its basic configuration is same as that of the plasma processing apparatus 100 of FIG. 2, except for the gas supply system. Accordingly, the same compartments will be indicated by the same reference characters, and descriptions thereof will be omitted.

The plasma processing apparatus 101 of FIG. 6 includes an N₂ gas supply source 19, and is configured to supply an N₂ gas therefrom. Instead of the N₂ gas, an NH₃ gas or a gaseous mixture of N₂ and H₂, for example, may be used as the processing gas of the nitriding process. Further, other rare gases, such as Kr, Xe, He and others, may be used instead of the Ar gas.

The conditions for the nitriding process using the plasma processing apparatus 101 are not specifically limited. For example, the flow rate of the rare gas such as Ar is set to be 100 to 3000 mL/min(sccm), the flow rate of the N₂ gas is set to be 10 to 1000 mL/min(sccm), the inside of the chamber is adjusted to be at the processing pressure of 1.3 to 1333 Pa (10 mTorr to 10 Torr), and the wafer W is heated to a temperature of 300 to 500° C. Further, preferably, the power of the microwave generator 39 may be 0.5 to 5 kW.

Under the aforementioned conditions, the plasma nitriding process as illustrated in FIG. 5C is performed to form the silicon oxynitride film (SiON film) in the vicinity of the surface of the silicon oxide film 113.

Further, also in the plasma processing apparatus 101 of FIG. 6, the nitriding process may be performed without the plate 60. However, preferably, the plate 60 having the through holes 60a may be used to attenuate the energy of nitrogen ions in the plasma. In this manner, the plasma damage can be suppressed.

In the aforementioned nitriding process, to suppress the leakage current in the transistor including the gate insulating film 114, it is preferable that a concentration of nitrogen (N) existing in the SiON film to be formed is set to be 1 to 25%; more preferably, 5 to 15%; and most preferably, 8 to 12%. Further, in accordance with the present embodiment, when performing the plasma nitriding process, the nitrogen can be uniformly distributed at a high concentration near the surface of the gate oxide film, and the SiON film can be formed such that the nitrogen does not exist in a vicinity of the interface between the SiON film and the silicon substrate.

After the nitriding process, an annealing process may be performed if necessary. The annealing process following the nitriding process may be performed by using, for example, a rapid thermal process (RTP) apparatus to heat the wafer W for a short time of about 10 to 30 seconds under the pressure of 133.3 Pa (lTorr) at the wafer temperature of at least 1000° C. in an atmosphere of a low-partial-pressure oxygen or inactive gas(s) such as N₂ and Ar. Thus, the interface between the silicon substrate and the insulating film is made smoother, the quality of the insulating film is improved, and a nitrogen desorption is suppressed to form a stable insulating film.

By performing each of the aforementioned processes (FIG. 5D), the gate insulating film 114 can be formed.

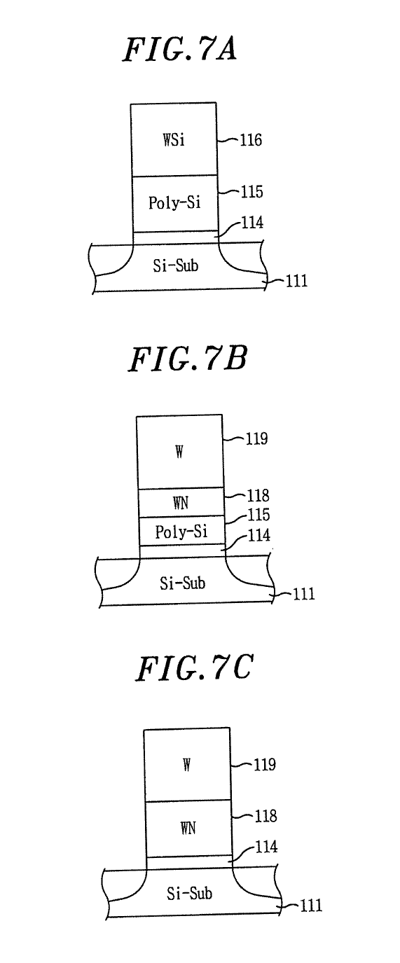

The method in accordance with the present invention can be used for fabricating a semiconductor device such as a MOS transistor, and can be applied to, for example, fabricating a semiconductor device having a gate electrode structure as illustrated in FIGS. 7A to 7C, in which an isolation region, an oxide film on a sidewall of the gate electrode, side walls and the like are not shown.

FIGS. 7A and 7B illustrate semiconductor devices having poly metal gates. FIG. 7A illustrates a tungsten polycide structure formed by, in accordance with the method of the present invention, forming the gate insulating film 114 of silicon oxide (SiO₂) or silicon oxynitride (SiON) on the Si substrate 111, and depositing a polysilicon layer 115 and a tungsten silicide (WSi) layer 116 as a gate electrode. FIG. 7B illustrates a tungsten polymetal structure formed by, in accordance with the method of the present invention, forming the gate insulating film 114 of SiO₂ or SiON on the Si substrate 111, and depositing a polysilicon layer 115, a barrier layer 118 of tungsten nitride (WN) or the like, and a tungsten layer 119 as a gate electrode. FIG. 7C illustrates a tungsten metal gate structure by forming the gate insulating film 114 of SiO₂ or SiON on the Si substrate 111, and depositing the barrier layer 118 and the tungsten layer 119 of tungsten nitride (WN) or the like on the gate insulating film 114.

In FIG. 7A, the tungsten silicide layer 116 is used as a metal silicide layer; and in FIGS. 7B and 7C, the tungsten layer 119 is used a the metal layer. However, the metal silicide layer or the metal layer may be formed of other metals, for example, copper, platinum, titanium, molybdenum, nickel and copper.

Hereinafter, the sequence of fabricating the gate electrode structure illustrated in FIG. 7B will be described as an example. First, the Si substrate 111 whose surface has been cleaned by a DHF (diluted hydrofluoric acid) cleaning is doped with P+ or N+ to form a well region (diffusion region). Subsequently, by using the plasma processing apparatus 100 of FIG. 2, the plasma oxidation process is performed at a temperature above 700° C. under the aforementioned conditions to form the SiO₂ layer on the surface of the Si substrate. It is preferable that, thereafter, the plasma nitriding process is performed on the surface of the SiO₂ layer by using the plasma processing apparatus 101 of FIG. 6 under the aforementioned conditions to form the SiON film. If necessary, the annealing process is performed at a temperature of about 1000° C. in an inactive atmosphere of, e.g., nitrogen, thereby forming the gate insulating film 114.

Subsequently, the polysilicon layer 115 is formed on the gate insulating film 114 by, for example, a CVD method. Then, the barrier layer 118 is formed thereon, and the tungsten layer 119 is formed by using tungsten, which is an electrode material of a high melting point. The tungsten layer 119 may be formed by using, for example, a CVD method or a sputtering method. Further, in this example, tungsten nitride is used for the barrier layer 118.

A hard mask layer (not shown) of, e.g., silicon nitride is formed on the tungsten layer 119, and a photoresist layer (not shown) is formed. Then, the hard mask layer is etched by using the photoresist layer as a mask according to the photolithographic technology, and the tungsten layer 119, the barrier layer 118 and the polysilicon layer 115 are sequentially etched by using the photo resist layer and the hard mask layer, or only the hard mask layer, as a mask. In the meantime, an ashing or a cleaning is performed at a necessary timing, and a sidewall (not shown) is formed to finally fabricate the gate electrode. By using the gate electrode formed by the aforementioned process, a high-quality transistor can be fabricated such that the leakage current is small and the driving current is large.

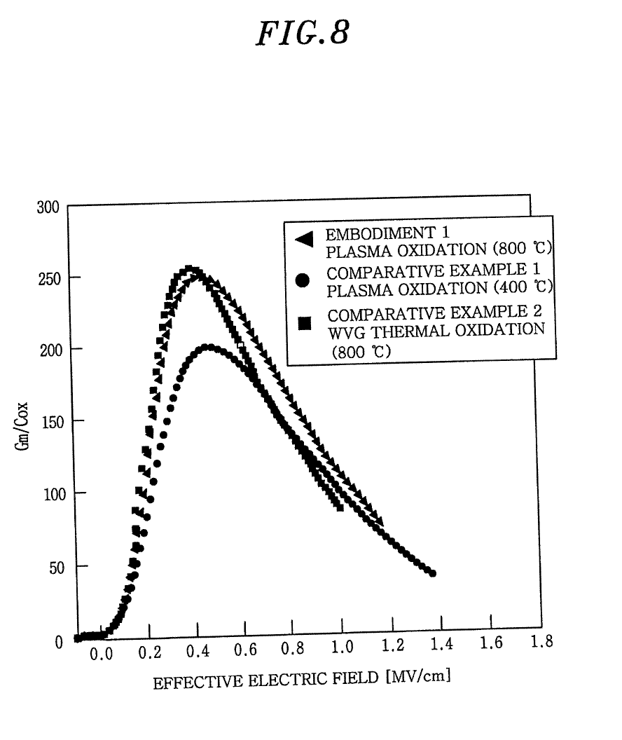

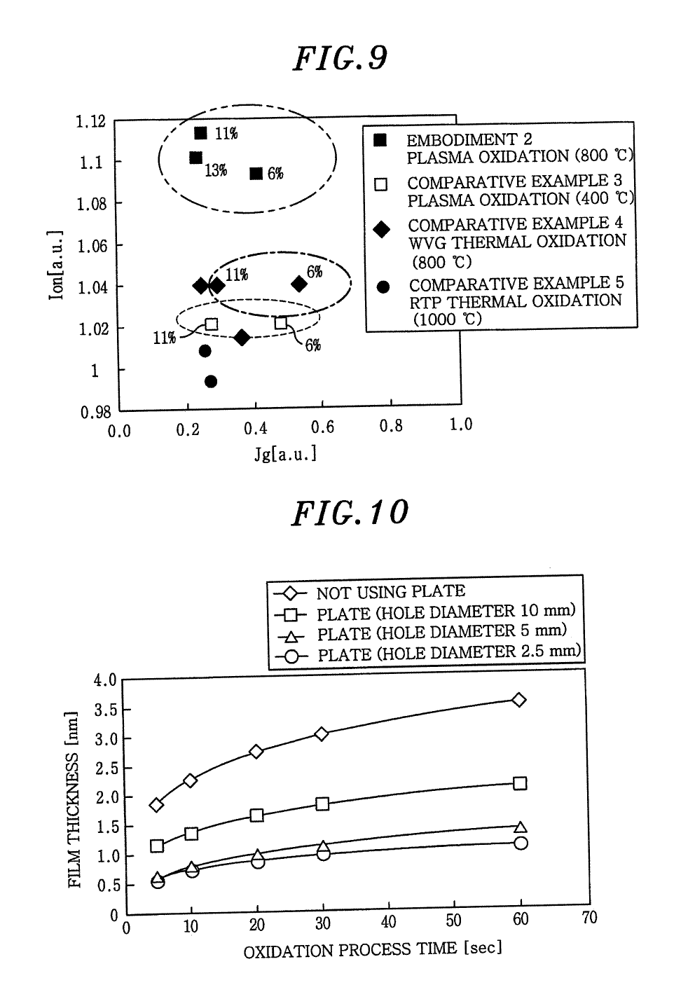

In the following, the results of experiments for verifying the effects of the present invention will be described with reference to FIGS. 8 and 9.

### Embodiment 1

### Oxide Film Formed by the High-Temperature Plasma Oxidation Process in Accordance with the Present Invention; 800° C.

An oxide film was formed by the high-temperature plasma oxidation process on the Si substrate 111 using the plasma processing apparatus 100. The oxide film was used for the gate insulating film 114 whose film thickness is 1.0 nm (without performing the nitriding process). A transistor was fabricated by using the gate insulating film 114 formed by the method in accordance with the present invention, and forming a gate electrode of the structure illustrated in FIG. 7A.

The conditions for the plasma process in the oxidation process were as follows: the plate 60 having the through holes 60a with the diameter of 2.5 mm was used, Ar and O₂ were used as the processing gases at the flow rate ratio of 2000/10 μL/min(sccm)], the wafer temperature as 800° C., the pressure was 66.7 Pa (500 mTorr), the power supplied to the plasma was 2.0 kW, and the processing time was 7 seconds.

### Comparative Example 1

### Oxide Film Formed by a Low-Temperature Plasma Oxidation Process; 400° C.

An oxide film with the film thickness of 1.0 nm was formed by a method same as that of Embodiment 1 except that the oxidation processing temperature was 400° C., and the oxide film was used as the gate insulating film 114. Likewise as Embodiment 1, the gate electrode was formed to fabricate a transistor.

### Comparative Example 2

### Oxide Film Formed by a WVG Thermal Oxidation Process; 800° C.

The Si substrate 111 was subject to a thermal oxidation process at 800° C. by using an oxidation furnace provided with a water vapor generator (WVG) to form a thermal oxide film with the film thickness of 1.0 nm, which was used as the gate insulating film 114. Likewise as Embodiment 1, the gate electrode was formed to fabricate a transistor.

FIG. 8 illustrates the results of measuring the transfer conductance Gm with respect to the above-described transistors. In FIG. 8, the vertical axis represents Gm/Cox, i.e., the transfer conductance divided by an electric capacitance Cox of the oxide film; and the horizontal axis represents an effective electric field.

It was revealed therefrom that the transistor of Embodiment 1 using the plasma processing apparatus 100 and the gate insulating film 114 formed by the oxidation process at a high temperature (800° C.) had a high Gm value at a high electric field, and showed electrical characteristics better than the transistor using the gate insulating film 114 formed by the plasma oxidation process at 400° C. (of Comparative Example 1) or the thermal oxidation process (of Comparative Example 2). That is, since the mobility of electrons was great and the current gain was enhanced in the transistor of Embodiment 1 whose Gm value was high at a high electric field, the transistor had characteristics of a high speed and a good stability.

The reason why the transistor of Embodiment 1 had a high Gm value at a high electric field since is conjectured as follows: the gate insulating film 114 formed by oxidizing silicon at a high temperature above 600° C. using the plasma processing apparatus 100 had a low interface roughness between SiO₂ and Si, so that interface roughness scattering was suppressed.

### Embodiment 2

### Oxide Film Formed by the High-Temperature Plasma Oxidation Process; 800° C.

An oxide film was formed by the high-temperature plasma oxidation process on the surface of the Si substrate 111, which had been cleaned by a 1% DHF solution, using the plasma processing apparatus 100. The gate insulating film 114 was formed by nitriding the oxide film using the plasma processing apparatus 101 of FIG. 1, and performing the annealing process on the nitrided oxide film in the heating unit 136. A transistor was fabricated by using the gate insulating film 114 and forming the gate electrode of the structure illustrated in FIG. 7A. The film thickness of the gate insulating film 114 was set to be about 1 nm. Here, it is preferably that the oxidation process, the nitriding process and the annealing process are performed continuously with vacuum exhausting.

The conditions for the plasma process in the oxidation process was as follows: the plate 60 having the through holes 60a with the diameter of 2.5 mm was used, Ar and O₂ were used as the processing gases at the flow rate ratio of 2000/10 μL/min(sccm)], the wafer temperature was 800° C., the pressure was 66.7 Pa (500 mTorr), the power supplied to the plasma was 2.0 kW, and the processing time was 7 seconds.

Further, the conditions for the plasma process in the nitriding process was as follows: the plate 60 having the through holes 60a with the diameter of 10 mm was used, Ar and N₂ were used as the processing gases at the flow rate ratio of 2000/40 μL/min(sccm)], the wafer temperature was 400° C., the pressure was 6.7 Pa (50 mTorr), and the power supplied to the plasma was 1.5 kW. To form an oxynitride film, the nitriding process was performed by controlling the processing time to be 8, 17.5 or 24 second so that the nitrogen concentration in the SiON film was 6%, 11% or 13%.

The conditions for the annealing process after the nitriding process was as follows: the rapid thermal process (RTP) apparatus was used, O₂/N₂ was equal to 1/1 μL/min (slm)], the pressure was 133.3 Pa (1 Torr), the wafer temperature was 1000° C., and the processing time was 20 seconds.

Further, for comparison, transistors manufactured by the following methods were tested as well.

### Comparative Example 3

### Oxide Film Formed by the Low-Temperature Plasma Oxidation Process; 400° C.

The gate insulating film was formed and a transistor was fabricated by a method same as Embodiment 2, except that the temperature of the plasma oxidation process was 400° C.

### Comparative Example 4

### Oxide Film Formed by the Wvg Thermal Oxidation Process; 800° C.

A thermal oxide film formed at 800° C. by using the oxidation furnace including the water vapor generator (WVG) was, as in Embodiment 2, nitrided using the plasma processing apparatus 101 and then anneal-processed to thereby form the gate insulating film 114 and fabricate a transistor.

### Comparative Example 5

### Oxide Film Formed by a RTP Thermal Oxidation Process; 1000° C.

A thermal oxide film was formed by the thermal oxidation process using the rapid thermal process (RTP) apparatus under the conditions of: O₂/N₂ equal to 1/1 μL/min (slm)], the pressure of 133.3 Pa (1 Torr), the temperature of 1000° C. and the processing time of 5 seconds. Under the conditions same as those of Embodiment 2, the thermal oxide film was nitrided using the plasma processing apparatus 101 and then anneal-processed to thereby form the gate insulating film 114 and fabricate a transistor.

An Iₒₙ-Jg plot of the above-described transistors was made, which is illustrated in FIG. 9. In FIG. 9, the vertical axis represents “Iₒₙ” at a threshold voltage of +0.7V, which is normalized by the value of Iₒₙ of the gate insulating film 114 in Comparative Example 4 (WVG thermal oxidation process at 800° C.). The horizontal axis represents “Jg” at a threshold voltage of +0.7V, which is normalized by the value of Jg in Comparative Example 4. Herein, Iₒₙ means an on-current (i.e., driving current), and Jg means a leakage current that flows through the gate insulating film 114 per unit area. Accordingly, it can be seen that the leakage current decreases and the driving current increases as moving to the upper left in the graph of FIG. 9, which indicates that the current driving efficiency of the transistor is good.

Further, in FIG. 9, “6%”, “11%” and “13%” represent the N concentration in the gate insulating film 114.

It was revealed from the results of FIG. 9 that the transistor in Embodiment 2, whose gate insulating film 114 was formed of silicon oxynitride (SiON) obtained by nitriding the silicon oxide (SiO₂) film that had been plasma-oxidized at a high temperature (800° C.) using the plasma processing apparatus 100, had a current driving efficiency better than those of the transistors in Comparative Examples 3 to 5, whose gate insulating film 114 was obtained by nitriding the oxide film that had been plasma-oxidized at a low temperature of 400° C. using the plasma oxidation process, or nitriding the thermal oxide film on which the WVG or RTP thermal oxidation process had been performed. It is estimated that such difference in the current driving efficiency was caused by the difference between the film qualities of the oxide films from which the oxynitride films were formed. In the present embodiment, the plasma oxidation process was performed at 8000C. However, if a transistor includes the gate insulating film 114 formed by nitriding the oxide film which has been formed by being oxidized at a temperature above 600° C. in accordance with the method of the present invention, the transistor has a good mobility characteristic and a high response speed, and is capable of reducing a power consumption. Further, it is preferable that the N concentration of the oxynitride film is set to be within a range from 1 to 25%.

Further, the gate insulating film 114 formed from an oxide film obtained by being oxidized at 800° C. using the plasma processing apparatus 100 has such good characteristics that, even if that gate insulating film 114 is a thin film of about 1 nm, the transistor using that gate insulating film 114 can suppress the leakage current while showing a current driving efficiency higher than a transistor whose gate insulating film 114 is formed from the thermal oxide film. Therefore, it was revealed that, in accordance with the method of the present invention, the gate insulating film 114 of high quality can be formed within a range of film thickness from 0.2 to 10 nm (preferably, 0.5 to 2.0 nm; and more preferably, 0.8 to 1.2 nm).

Hereinafter, the results of an experiment, in which it was tested how the diameter of the through holes 60a in the plate 60 affected on the thickness of the oxide film formed on the Si substrate in the plasma oxidation process using the plasma processing apparatus 100, will be described with reference to FIGS. 10 to 12. In the experiment, three kinds of plate were used as the plate 60. One of the plates has through holes 60a whose diameter were 10 mm (the number of holes were 626); another has through holes 60a whose diameter were 5 mm (the number of holes were 629); and the other has through holes 60a whose diameter were 2.5 mm (the number of holes were 2701). Further, the plasma oxidation process was also performed without using the plate 60.

The conditions for the plasma oxidation process was as follows: Ar and O₂ were used as the processing gases at the flow rate ratio of 1000/5 μL/min(sccm)]; the wafer temperature was 800° C.; the pressure was 66.7 Pa (500 mTorr); the power supplied to the plasma was 2.0 kW; and the processing time were varied from 5 to 60 seconds. Under the above conditions, the thickness of the oxide film was measured.

As shown in FIG. 10, when no plate was used, an oxidation rate was high so that the oxide film was formed in a short time. Further, the oxide film was of high quality and uniform. However, without using a plate, it was difficult to form the oxide film with a thickness of 1 to 2 nm or less.

On the other hand, it can be seen that, by using the plate 60, a growth of the oxide film was restrained so that an ultra thin film could be formed, unlike the case without the plate 60. In this case, as the diameter of the holes in the plate 60 gets smaller, the growth rate (oxidation rate) of the oxide film gets further restrained.

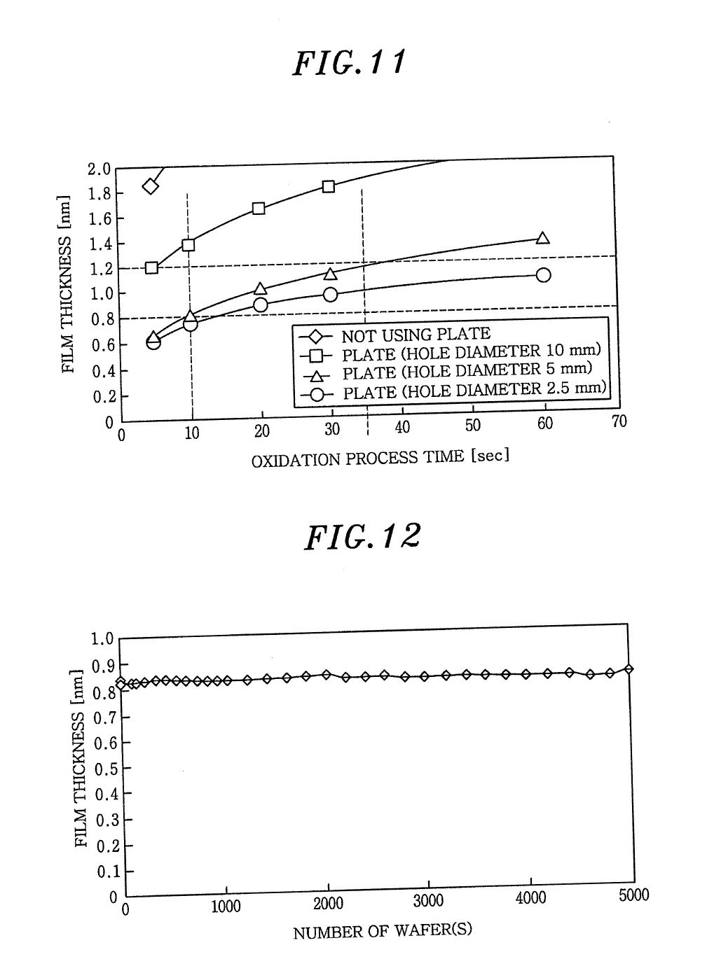

FIG. 11 is an enlarged view of the graph of FIG. 10 within the range of 0.5 to 2.0 nm of the thickness of the oxide film. It can be seen therefrom that it is effective to set the diameter of the holes in the plate 60 to be 5 to 2.5 mm in forming a thin film whose thickness ranges from 0.5 to 1.5 nm or less. Further, especially by using the plate 60 in which holes with the diameter of 5 mm was used, even in the high temperature process of 800° C., the thickness of the oxide film could be controlled within the range from about 0.8 to 1.2 nm at a high speed only by varying the processing time between 10 to 35 seconds. Thus, the oxide film of high quality can be formed uniformly and densely in a short time.

FIG. 12 shows a change in the thickness of the silicon oxide film on the wafer W when running tests of the plasma oxidation process were performed for 5000 wafers W using the plasma processing apparatus 100 provided with the plate 60 having the holes with the diameter of 5 mm. In the tests, Ar and O₂ (Ar/O₂) were used as the processing gases at the flow rate ratio of 1000/5 μL/min(sccm)], the wafer temperature was 800° C., the pressure was 66.7 Pa (500 mTorr), the power supplied to the plasma was 2.0 kW, and the processing time was 10 seconds. A target thickness of the silicon oxide film was set to be as small as 0.8 to 1.2 nm. It is revealed from FIG. 12 that, in forming the thin film of 0.5 to 2.0 nm, the silicon oxide film can be formed with a high reproducibility by the high temperature process of 800° C. In these running tests, an average film thickness was 0.8309 nm and an inter-wafer surface uniformity in the film thickness was 0.621% Sigma. It is estimated that this is because the active species in the plasma was uniformized at a vicinity of the surface of the wafer W by controlling an amount of ions by using the plate 60.

Table 1 shows the results of measuring the in-surface uniformity of the thickness of the silicon oxide film on the wafer W by using a single wavelength ellipsometer when the plasma oxidation process was performed on the wafer W using the plasma processing apparatus 100 provided with the plate 60. The conditions for the plasma oxidation process were the same as those of the running tests. In Table 1, Class A represents the in-surface uniformity in case of using the plate 60 having the holes with the diameter of 2.5 mm and setting the target film thickness to be 1.0 nm; Class B represents the in-surface uniformity in case of using the plate 60 having the holes with the diameter of 2.5 mm and setting the target film thickness to be 1.2 nm; and Class C represents the in-surface uniformity in case of using the plate having the holes with the diameter of 10 mm and setting the target film thickness to be 1.7 nm. Further, “σ” in Table 1 means the standard deviation of the film thickness, and “σ/average film thickness” represents a standard deviation normalized by the average film thickness (nm).

TABLE 1

| | Class A | Class B | Class C |
|---|---|---|---|
| hole diameter [mm] | 2.5 | 2.5 | 10 |
| average film thickness [nm] | 1.0196 | 1.2161 | 1.7334 |
| σ/average film thickness [%] | 0.935 | 1.229 | 0.465 |

It was verified from Table 1 that, when the plate 60 was used, the in-surface uniformity of the oxide film thickness in the wafer W was about 1.23% or less, which is a favorable result.

Thereafter, the etching resistance, the interface roughness, the argon concentration and the film density were measured with respect to the silicon oxide film formed on the silicon substrate by using the plasma processing apparatus 100 according to the following methods.

(Method of Forming Silicon Oxide Film)

The WVG thermal oxidation process: performed at 900° C. (as a comparative sample).

The plasma oxidation process: performed under the following conditions: Ar and O₂ were used as the processing gases at the flow rate ratio of 1000/10 μL/min(sccm)], the output power of the microwave was 2000 W, the processing pressure was 26.6 Pa, 66.7 Pa or 533.3 Pa, and the processing temperature was 400° C., 600° C., 700° C. or 800° C.

(Etching Resistance)

The etching resistance was evaluated by performing a wet etching process on each silicon oxide film for 30 seconds by using a diluted hydrofluoric acid (DHF) of 0.5% concentration (pure water/50% HF=100/1), measuring the film thickness before and after the etching by the ellipsometer, and estimating an etching rate.

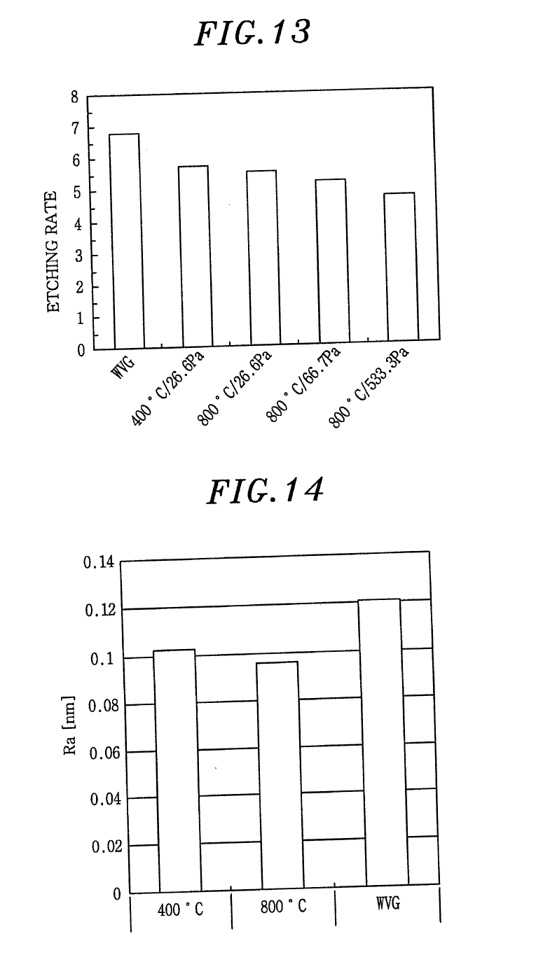

FIG. 13 shows the results of measuring the etching resistance. In FIG. 13, the vertical axis represents a normalized etching rate. It was revealed from FIG. 13 that the silicon oxide film formed by the plasma oxidation process at 800° C. had an etching resistance better than that of the silicon oxide film formed by the WVG thermal oxidation process or the plasma oxidation process at 400° C. Therefore, it was confirmed that the silicon oxide film formed by the high temperature plasma oxidation process of 800° C. was dense and of a good quality.

(Interface Roughness)

After immersing the wafer W having the silicon oxide film formed thereon in the 0.5% diluted hydrofluoric acid solution to remove the silicon oxide (SiO₂) film, the interface roughness (Ra) of an exposed silicon interface was measured by a surface roughness tester. FIG. 14 shows the results. It was confirmed from FIG. 14 that the interface between the silicon and the silicon oxide film formed by the high temperature plasma oxidation process at 800° C. (under the processing pressure of 26.6 Pa) had a favorably small interface roughness compared to that of the interface between silicon and the silicon oxide film formed by the low temperature plasma oxidation process performed at 400° C. (under the processing pressure of 26.6 Pa) or by the WVG thermal oxidation process performed at 9000C. The low interface roughness contributes to a suppression of the leakage current.

(Argon Concentration)

The argon concentration in each silicon oxide film was measured by a total reflection X-ray fluorometric analysis (Trex). As a result, the argon concentration of the silicon oxide film formed by the plasma oxidation process at the processing temperature of 400° C. (under the pressure of 26.6 Pa) was higher than 7×10¹⁰ [atoms/cm²]. However, the argon concentrations in the other silicon oxide films formed by the plasma oxidation process respectively at the processing temperatures of 600° C., 700° C. and 800° C. (under the pressure of 26.6 Pa in all cases) were all lower than or equal to 1×10¹⁰ [atoms/cm²], which did not excel a level of the argon concentration of the silicon oxide film formed by the WVG thermal oxidation process, indicating that the film qualities thereof were of a high quality (the illustration of the results is omitted).

(Film Density)

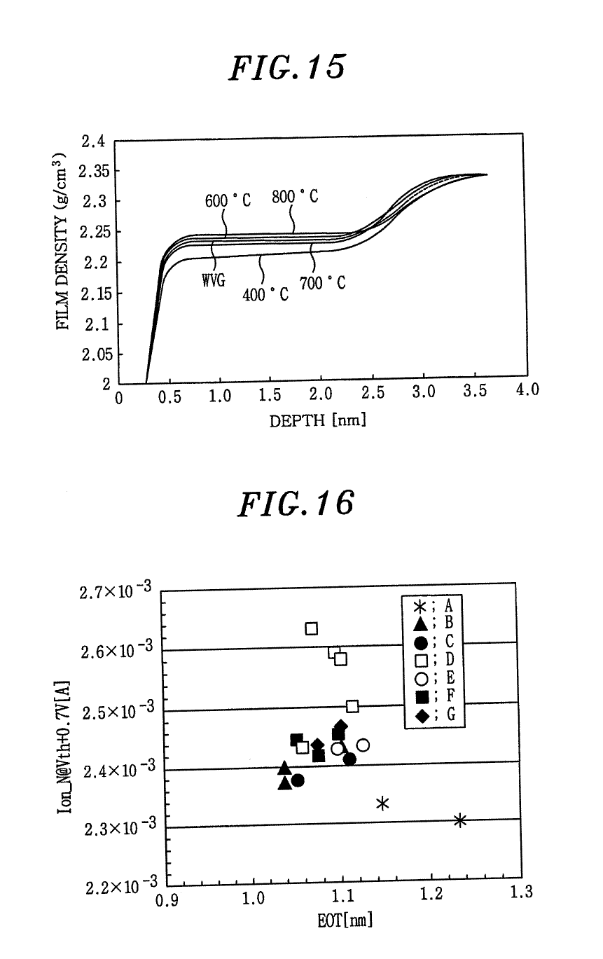

The film density was measured by a grazing incidence X-ray reflectometry (GIXR). The results thereof are illustrated in FIG. 15. As shown therein, the film densities of the silicon oxide films formed by the plasma oxidation process at the processing temperatures of 600° C., 700° C. and 800° C. (under the pressure of 26.6 Pa in all cases) are obviously higher than that of the silicon oxide film formed by the plasma oxidation process at the processing temperature of 400° C. (under the pressure of 26.6 Pa), and have a same profile as that of the silicon oxide film formed by the WVG thermal oxidation process.

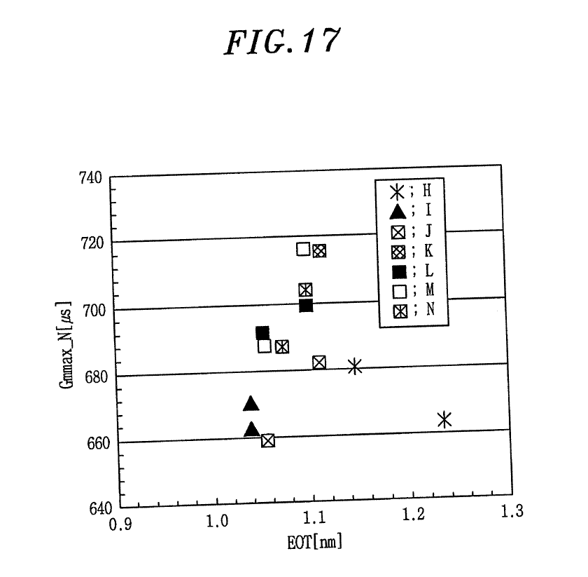

Subsequently, an NMOS transistor was made by using, as a gate insulating film, the silicon oxide films and silicon nitride layers formed respectively under different conditions, the electrical characteristics of each NMOS transistor are evaluated. FIG. 16 illustrates the relationship between the equivalent oxide thickness (EOT) of the gate insulating film and Iₒₙ at the threshold voltage of +0.7V; and FIG. 17 illustrates the relationship between the equivalent oxide thickness (EOT) of the gate insulating film and the maximum value (Gₘₘₐₓ) of the transfer conductance.

In FIGS. 16 and 17, reference characters A to N indicate the following test classes:

A: WVG thermal oxidation process at 900° C.;

B: WVG thermal oxidation process at 900° C.+plasma nitriding process;

C: plasma oxidation process at 400° C. and under 106.6 Pa (using the plate having holes with the diameter of 10 mm)+plasma nitriding process;

D: plasma oxidation process at 800° C. under 66.7 Pa+plasma nitriding process;

E: plasma oxidation process at 400° C. under 66.7 Pa+plasma nitriding process;

F: plasma oxidation process at 800° C. under 106.6 Pa (using the plate having holes with the diameter of 10 mm)+plasma nitriding process;

G: plasma oxidation process at 650° C. under 106.6 Pa (using the plate having holes with the diameter of 10 mm)+plasma nitriding process;

H: WVG thermal oxidation process at 900° C.;

I: WVG thermal oxidation process at 900° C.+plasma nitriding process;

J: plasma oxidation process at 400° C. under 106.6 Pa (using the plate having holes with the diameter of 10 mm)+plasma nitriding process;

K: plasma oxidation process at 800° C. under 66.7 Pa+plasma nitriding process;

L: plasma oxidation process at 800° C. under 106.6 Pa (using the plate having holes with the diameter of 10 mm)+plasma nitriding process;

M: plasma oxidation process at 800° C. under 106.6 Pa (using the plate having holes with the diameter of 2.5 mm)+plasma nitriding process; and

N: plasma oxidation process at 650° C. under 106.6 Pa (using the plate having holes with the diameter of 10 mm)+plasma nitriding process.

The plasma oxidation process was performed under the following conditions: Ar and O₂ were used as the processing gases at the flow rate ratio of Ar/O₂=1000/5 μL/min(sccm)], the microwave power was 900 W, the processing pressure was 66.7 Pa (500 mTorr) or 106.6 Pa (800 mTorr), and the processing temperature was 400° C., 650° C. or 8000C. In addition, the plasma nitriding process was performed under the following conditions: Ar and N₂ were used as the processing gases at the flow rate ratio of Ar/N₂=1000/40 μL/min(sccm)], the microwave power was 1500 W, the processing pressure was 6.7 Pa (50 mTorr), and the processing temperature was 400° C. Further, the plasma nitriding process was continuously performed after the plasma oxidation process in the plasma processing apparatus of FIG. 1.

It was confirmed from FIGS. 16 and 17 that, when comparing on the basis of a same EOT, the gate insulating film using the silicon oxynitride (SiON) film formed by the plasma nitriding process following the plasma oxidation process at the high temperature of 800° C. showed the values of Iₒₙ and Gmₘₐₓ noticeably higher than those of the gate insulating film using the silicon oxide (SiO₂) film formed by the WVG thermal oxidation process or the silicon oxynitride (SiON) film formed by the plasma nitriding process following the plasma oxidation process at 400° C., and thus indicated good electrical characteristics. Therefore, it became apparent that the silicon oxide film formed by the high temperature plasma oxidation process higher than or equal to 600° C., and the silicon oxynitride film formed by nitriding that silicon oxide film can be preferably used for various semiconductor devices.

So far, the embodiments of the invention have been described. However, the present invention should not be construed to be limited thereto, and various modifications may be made therefrom.

For example, although the microwave plasma processing apparatuses 100 and 101 for exciting plasma by the microwaves with the frequency of 300 MHz to 300 GHz were shown in FIGS. 2 and 6, a high frequency plasma processing apparatus which excites plasma by using a high frequency of 30 kHz to 300 MHz may also be used.

Further, although the plasma processing apparatus 100 of the RLSA type was shown in FIG. 2, a plasma processing apparatus of, for example, remote plasma type, ICP plasma type, ECR plasma type, surface wave plasma type, magnetron plasma type, or the like may also by used.

Further, although the plasma processing apparatus 100 was shown to have a single plate 60 in FIGS. 2 and 6, if necessary, two or more plates may be stacked to be provided therefor. An opening area, an opening ratio or the like of the through holes 60a may be properly adjusted depending on an object or processing conditions of the plasma process.

Further, in the plasma processing apparatus 100 of FIG. 2, the plasma oxidation process may be performed by adding an H₂ gas supply source (not shown) to the Ar gas supply source 17 and the O₂ gas supply source 18 in the gas supply system 16 to thereby blend the H₂ gas with the Ar gas and the O₂ gas at a specified flow rate. By mixing the H₂ gas in an appropriate amount, a native oxide film can be removed from the Si substrate 111, so that the silicon oxide film 113 of high quality can be formed.

Further, in the above embodiments, the nitriding process was described to be performed by using the plasma processing apparatus 101 of the RLSA type, but the apparatus or conditions for the nitriding process should not be construed to be limited thereto. The nitriding process may also be performed by using plasma processing apparatus of the other types, for example, remote plasma type, ICP plasma type, ECR plasma type, surface wave plasma type, magnetron plasma type and the like, under proper conditions.

### INDUSTRIAL APPLICABILITY

The present invention is preferably used in fabricating various semiconductor devices such as transistors.

What is claimed is:

1. A method of forming an insulating film, comprising:
performing an oxidation process to form a silicon oxide film by applying oxygen-containing plasma onto silicon in a surface of an object to be processed in a processing chamber of a plasma processing apparatus,
wherein a processing temperature in the oxidation process is higher than 600° C. and lower than or equal to 1000° C., and
wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

2. The method of claim 1, wherein, in the oxidation process, a dielectric plate having a plurality of through holes is interposed between a plasma generation region and the object to be processed in the processing chamber.

3. The method of claim 2, wherein each of the though holes has a diameter of 2.5 to 12 mm, and a ratio of a total opening area of the through holes to an area of the object to be processed in an area of the dielectric plate corresponding to the object to be processed is 10 to 50%.

4. The method of claim 1, wherein, in the oxidation process, a processing pressure is 1.33 to 1333 Pa.

5. The method of claim 1, wherein a thickness of the silicon oxide film is 0.2 to 10 nm.

6. A method of forming an insulating film, comprising:
performing an oxidation process to form a silicon oxide film by applying oxygen-containing plasma onto silicon in the surface of an object to be processed in a processing chamber of plasma processing apparatus; and
performing a nitriding process to form a silicon oxynitride film by applying nitrogen-containing plasma onto the silicon oxide film formed in the oxidation process,
wherein a processing temperature in the oxidation process is higher than 600° C. and lower than or equal to 1000° C., and
wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

7. The method of claim 6, wherein the nitrogen-containing plasma is formed by introducing a nitrogen-containing processing gas including at least a rare gas and a nitrogen gas into a processing chamber, and, at the same time, applying a high frequency wave or a microwave into the processing chamber via the antenna.

8. The method of claim 6, wherein the nitriding process and the oxidation process are performed in the same processing chamber.

9. The method of claim 6, wherein the nitriding process and the oxidation process are respectively performed in separate processing chambers connected to each other in a state capable of being vacuum exhausted.

10. The method of claim 6, wherein, in the oxidation process, a dielectric plate having a plurality of through holes is interposed between a plasma generation region and the object to be processed in the processing chamber.

11. The method of claim 10, wherein each of the though holes has a diameter of 2.5 to 12 mm, and a ratio of a total opening area of the through holes to an area of the object to be processed in an area of the dielectric plate corresponding to the object to be processed is 10 to 50%.

12. The method of claim 6, wherein, in the oxidation process, a processing pressure is 1.33 to 1333 Pa.

13. The method of claim 6, wherein a thickness of the silicon oxide film is 0.2 to 10 nm.

14. A control program running on a computer that is executed to control a plasma processing apparatus to perform an oxidation process for forming a silicon oxide film by applying oxygen-containing plasma onto silicon of the surface in an object to be processed in a processing chamber of the plasma processing apparatus,
wherein a processing temperature in the oxidation process is higher than 600° C. and lower than or equal to 1000° C., and
wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

15. A computer-readable storage medium that stores a control program running on a computer,
wherein the control program is executed to control a plasma processing apparatus to perform an oxidation process for forming a silicon oxide film by applying oxygen-containing plasma onto silicon of the surface in an object to be processed in a processing chamber of the plasma processing apparatus,
wherein a processing temperature in the oxidation process is higher than 600° C. and lower than or equal to 1000° C., and
wherein the oxygen-containing plasma is formed by introducing an oxygen-containing processing gas including at least a rare gas and an oxygen gas into the processing chamber, and, at the same time, introducing a high frequency wave or a microwave into the processing chamber via an antenna.

16. A plasma processing apparatus comprising:
a plasma generation unit for generating plasma;
a processing chamber capable of being vacuum exhausted, for processing an object to be processed by the plasma;
a substrate supporting table on which the object to be processed is mounted in the processing chamber; and
a control unit for controlling to perform an oxidation process for oxidizing the object to be processed by oxygen-containing plasma formed by introducing an oxygen-containing processing gas including at least a rare gas and an oxygen gas into the processing chamber, and, at the same time, introducing a high frequency wave or a microwave into the processing chamber via an antenna at a processing temperature of higher than 600° C. and lower than or equal to 1000° C.

17. A method of forming a semiconductor device, comprising forming a gate electrode on the insulating film formed by the method of claim 1.

18. A method of forming a semiconductor device, comprising forming a gate electrode on the insulating film formed by the method of claim 6.
